(19) United States
(12) Patent Application Publication
(10) Pub. No.: US 2008/0158864 A1
(43) Pub. Date: Jul. 3, 2008

(54) Monolithic photo-chip with solar device and light-emitting device and manufacturing method thereof

(75) Inventors: Li-Hung Lai, Taichung City (TW); Kun-Fang Huang, Taichung (TW); Wen-Sheng Hsieh, Taichung (TW); Li-Wen Lai, Hsinchu Hsien (TW)

Correspondence Address: BACON & THOMAS, PLLC, 625 SLATERS LANE, FOURTH FLOOR, ALEXANDRIA, VA, 22314, US

(73) Assignees: HIGHER WAY ELECTRONIC CO., LTD., Taichung City (TW); Millennium Communication Co., Ltd, Hsinchu Hsien (TW)

(21) Appl. No.: 11/646,379

(22) Filed: Dec. 28, 2006

(51) Int. Cl. F21L 4/08; H01L 33/00; H01S 5/026

(52) U.S. Cl. 362/183; 372/50.21; 257/80; 438/24; 257/E33.077

(57) ABSTRACT

A monolithic photo-chip with a solar device and a light-emitting device that can be manufactured by utilizing a method of selective area growth (SAG) is provided, which has the advantages of simple structure, compactness and cost-effectiveness. Moreover, a solar-powered illuminator including the monolithic photo-chip and a rechargeable battery is provided, which has the advantages of small size, compactness, simple integration, easy installation and cost-effectiveness. Accordingly, the solar-powered illuminator is very suitable for versatile application fields, such as the LD application field including a laser pointer, a laser sight, a laser aiming device, a laser level and a laser measuring tool, etc; or the LED application field including a decoration lamp, a courtyard lamp, a garden lamp and a advertisement lamp, a streetlamp, a warning sign and a indication sign for the road application, etc.

### BACKGROUND OF THE INVENTION

1. Field of the Invention

The present invention relates to a monolithic photo-chip, and more particularly, to the monolithic photo-chip with a solar device and a light-emitting device.

2. Description of the Prior Art

Solid-state lighting sources, such as the light emitting diode (LED) and the laser diode (LD), become more and more cost-effective as the technology advances. LED and LD have the advantages of small volume, electricity saving, long life, glass free and toxic-gases free, etc. There are versatile LEDs, which includes red LEDs, blue LEDs, green LEDs and white LEDs, can be applied in many lighting application fields according to different usages, such as decoration, indication, display and illumination. Meanwhile, LD is widely applied as the lighting source of a laser pointer, a laser sight, a laser aiming device, a laser level and a laser measuring tool, etc.

On the other hand, solar cells are increasingly used as the clean energy sources because the oil is getting more and more shorted and expensive, and the solar energy is free and never used out. The solar chip of the light-focus type is usually compound-based, such as GaAs-based, InGaAs-based, CdTe-based, AlGaAs-based or Culn(Ga)Se2-based, which has the advantage of high photo-voltaic efficiency. Therefore, it is getting more and more popular nowadays.

A solar-powered illuminator using the LED as the light-emitting device in the nighttime is commonly used for many applications, such as the streetlamp, the warning sign and the indication sign for the road application. Besides, it is also utilized as the outdoor decoration lamp, the courtyard lamp, the garden lamp and the advertisement lamp, etc. Conventionally, the solar-powered illuminator normally includes a LED chip, a solar chip, a rechargeable battery and a controller. The solar chip receives the sunlight during the daytime and converts the solar energy into the electrical energy to store in the rechargeable battery. During the nighttime, the controller controls the rechargeable battery to discharge the stored electrical energy to drive the LED chip to emit light. Accordingly, the merit of the conventional solar-powered illuminator is that it does not need to hard-wire a connection with an external electrical system or recharge the rechargeable battery by using an external electrical source. The hard-wiring is difficult, inconvenient and expensive, and the recharge process is time-consuming, messy, troublesome and expensive.

However, the solar chip and the LED chip are packaged separately, so the conventional solar-powered illuminator is complex for integration, bulky, and expensive.

### SUMMARY OF THE INVENTION

In order to solve the aforementioned problem of being complex, bulky, and expensive for the conventional solar-powered illuminator that the solar chip and the LED chip are packaged separately, one object of the present invention is to provide a monolithic photo-chip with a solar device and a light-emitting device and the manufacturing method thereof. The monolithic photo-chip of the present invention has the advantages of simple structure, compactness and cost-effectiveness.

One object of the present invention is to provide a solar-powered illuminator, which includes: a monolithic photo-chip with a solar device and a light-emitting device; and a rechargeable battery. The solar-powered illuminator in accordance with the present invention does not need to hard-wire a connection with an external electrical system or recharge a rechargeable battery by using an external electrical source, so it has the advantages of small size, compactness, simple integration, easy installation and cost-effectiveness.

Consequently, the solar-powered illuminator including a monolithic photo-chip with a solar device and a light-emitting device according to the present invention is very suitable for versatile application fields, such as the LD application field including a laser pointer, a laser sight, a laser aiming device, a laser level and a laser measuring tool, etc; or the LED application field including a decoration lamp, a courtyard lamp, a garden lamp and an advertisement lamp, a streetlamp, a warning sign and an indication sign for the road application, etc.

To achieve the objects mentioned above, one embodiment of the present invention is to provide a monolithic photo-chip with a solar device and a light-emitting device, which includes: a substrate; the solar device formed on the substrate; and the light-emitting device formed on the substrate and separated from the solar device at a distance.

To achieve the objects mentioned above, one embodiment of the present invention is to provide a solar-powered illuminator, which includes: a monolithic photo-chip with a solar device and a light-emitting device, and a rechargeable battery. The rechargeable battery is electrically connected to the solar device and the light-emitting device, wherein it is charged by the solar device and provides the light-emitting device with power.

To achieve the objects mentioned above, one embodiment of the present invention is to provide a method for manufacturing a monolithic photo-chip with a solar device and a light-emitting device, which includes the steps of: an initial step to provide a substrate; a first covering step to cover a first isolation layer on the substrate and form a first exposed region of the substrate; a first device forming step to form the first device on the first exposed region of the substrate by using an epitaxy technique and a lithography technique; a first etching step to etch back the first isolation layer; a second covering step to cover a second isolation layer on the substrate and surfaces of the first device and form a second exposed region of the substrate; a second device forming step to form a second device on the second exposed region of the substrate by using the epitaxy technique and the lithography technique; and a second etching step to etch back the second isolation layer. Wherein the first device is either a solar device or a light-emitting device, and the second device is either a light-emitting device or a solar device correspondingly.

Other objects, technical contents, features and advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a side-view schematic diagram to illustrate the structure of a monolithic photo-chip with a solar device and a light-emitting device according to one embodiment of the present invention; and

FIG. 2A to FIG. 2G are side-view schematic diagrams to illustrate the steps of a method for manufacturing a monolithic photo-chip with a solar device and a light-emitting device according to one embodiment of the present invention.

### DESCRIPTION OF THE PREFERRED EMBODIMENT

The detailed explanation of the present invention is described as following. The described preferred embodiments are presented for purposes of illustrations and description, and they are not intended to limit the scope of the present invention.

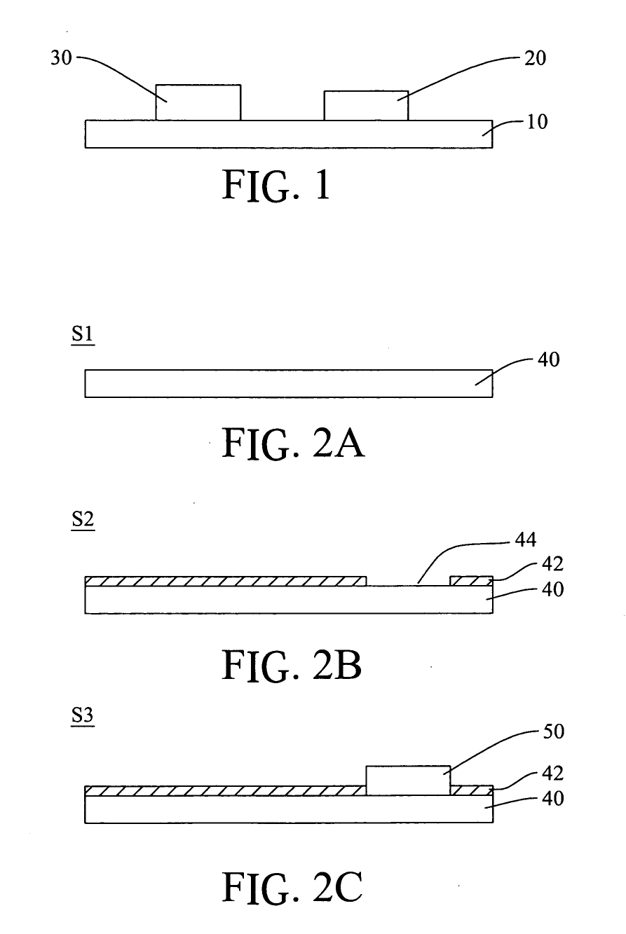

FIG. 1 is a side-view schematic diagram to illustrate the structure of a monolithic photo-chip with a solar device and a light-emitting device according to one embodiment of the present invention. A monolithic photo-chip with a solar device 20 and a light-emitting device 30 includes: a substrate 10; the solar device 20 formed on the substrate 10; and the light-emitting device 30 formed on the substrate 10 and separated from the solar device 20 at a distance. In one embodiment, the material of the substrate may be GaAs. The solar device 20 may be a single-junction solar cell or a multi-junction solar cell. The light-emitting device 30 may be a laser diode (LD), such as a side-illuminated LD or a vertical cavity surface emitting laser (VCSEL). The light-emitting device 30 may be a light emitting diode (LED), such as a red LED, a blue LED, a green LED and a white LED. Besides, the structure of the light-emitting device 30 may be selected from the group consisting of single heterostructure, double heterostructure and quantum well. The various kinds and structures for the aforementioned solar devices and the light-emitting devices are well known to the people skilled in the art, so they are not further described herein.

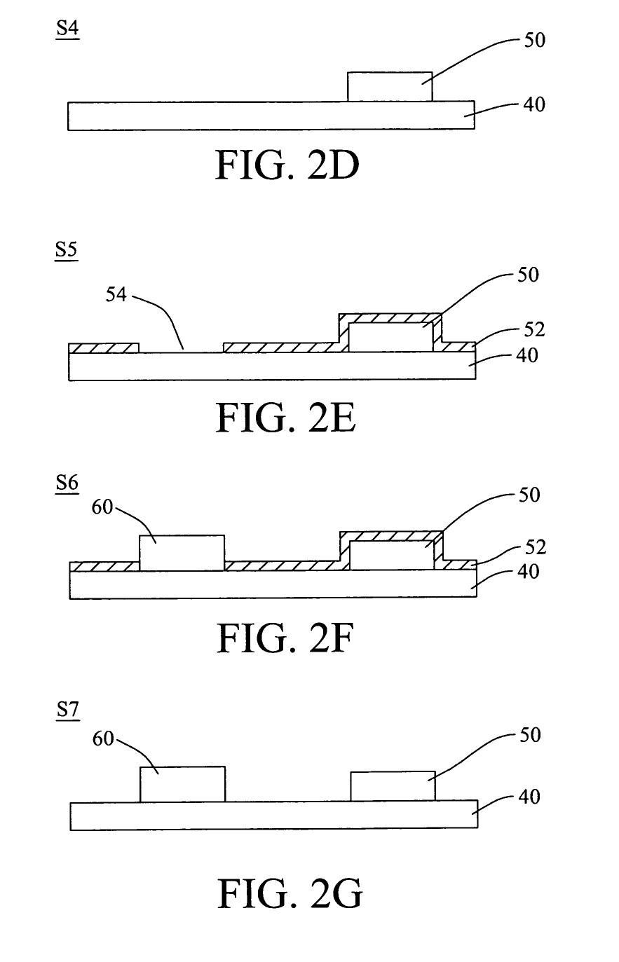

Next, please refer to FIG. 2A to FIG. 2G, which are side-view schematic diagrams to illustrate the steps of a method for manufacturing a monolithic photo-chip with a solar device and a light-emitting device according to one embodiment of the present invention. The method includes the steps of: an initial step S1 to provide a substrate 40; a first covering step S2 to cover a first isolation layer 42 on the substrate 40 and form a first exposed region 44 of the substrate 40; a first device forming step S3 to form a first device 50 on the first exposed region 44 of the substrate 40 by using an epitaxy technique and a lithography technique; a first etching step S4 to etch back the first isolation layer 42; a second covering step S5 to cover a second isolation layer 52 on the substrate 40 and surfaces of the first device 50 and form a second exposed region 54 of the substrate 40; a second device forming step S6 to form a second device 60 on the second exposed region 54 of the substrate 40 by using the epitaxy technique and the lithography technique; and a second etching step S7 to etch back the second isolation layer 52. Wherein the first device 50 is either a solar device or a light-emitting device, and the second device 60 is either a light-emitting device or a solar device correspondingly.

In one embodiment, the material of the first isolation layer 42 and the second isolation layer 52 is silicon oxide or silicon nitride. The material of the substrate 40, as the above-mentioned, may be GaAs. Moreover, the types and structures of the first device 50 and the second device 60 are similar to the solar device 20 and the light-emitting device 30, so they are not further described herein.

Accordingly, one feature of the present invention is that a monolithic photo-chip with a solar device and a light-emitting device can be manufactured by utilizing a method of selective area growth (SAG), as described in the preceding paragraphs.

To make a brief summarization, the present invention provides a monolithic photo-chip with a solar device and a light-emitting device, which has the advantages of simple structure, compactness and cost-effectiveness. Furthermore, It can be very convenient to integrate with a rechargeable battery to compose a solar-powered illuminator. For example, a solar-powered illuminator according to one embodiment of the present invention comprises: a monolithic photo-chip with a solar device and a light-emitting device of the present invention; and a rechargeable battery electrically connected to the solar device and the light-emitting device, wherein the rechargeable battery is charged by the solar device and provides the light-emitting device with power.

The solar-powered illuminator adopting the monolithic photo-chip with a solar device and a light-emitting device of the present invention does not need to hard-wire a connection with an external electrical system or recharge a rechargeable battery by using an external electrical source, which has the advantages of small size, compactness, simple integration, easy installation and cost-effectiveness. Consequently, it can be widely applied in many fields, such as the LD application field including a laser pointer, a laser sight, a laser aiming device, a laser level and a laser measuring tool, etc; or the LED application field including a decoration lamp, a courtyard lamp, a garden lamp and a advertisement lamp, a streetlamp, a warning sign and a indication sign for the road application, etc.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. A monolithic photo-chip with a solar device and a light-emitting device, comprising:
a substrate;
said solar device formed on said substrate; and
said light-emitting device formed on said substrate and separated from said solar device at a distance.

2. The monolithic photo-chip with a solar device and a light-emitting device according to claim 1, wherein the material of said substrate is GaAs.

3. The monolithic photo-chip with a solar device and a light-emitting device according to claim 1, wherein said solar device is a single-junction solar cell or a multi-junction solar cell.

4. The monolithic photo-chip with a solar device and a light-emitting device according to claim 1, wherein said light-emitting device is a laser diode (LD).

5. The monolithic photo-chip with a solar device and a light-emitting device according to claim 4, wherein said LD is a side-illuminated LD or a vertical cavity surface emitting laser (VCSEL).

6. The monolithic photo-chip with a solar device and a light-emitting device according to claim 1, wherein said light-emitting device is a light emitting diode (LED).

7. The monolithic photo-chip with a solar device and a light-emitting device according to claim 6, wherein said LED is selected from the group consisting of a red LED, a blue LED, a green LED and a white LED.

8. The monolithic photo-chip with a solar device and a light-emitting device according to claim 1, wherein the structure of said light-emitting device is selected from the group consisting of single heterostructure, double heterostructure and quantum well.

9. A solar-powered illuminator applying said monolithic photo-chip with a solar device and a light-emitting device according to claim 1, comprising:
said monolithic photo-chip with a solar device and a light-emitting device; and
a rechargeable battery electrically connected to said solar device and said light-emitting device, wherein said rechargeable battery is charged by said solar device and provides said light-emitting device with power.

10. A method for manufacturing a monolithic photo-chip with a solar device and a light-emitting device, comprising the steps of:
providing a substrate;
covering a first isolation layer on said substrate and forming a first exposed region of said substrate;
forming a solar device on said first exposed region of said substrate by using a epitaxy technique and a lithography technique;
etching back said first isolation layer;
covering a second isolation layer on said substrate and surfaces of said first device and forming a second exposed region of said substrate;
forming a light-emitting device on said second exposed region of said substrate by using said epitaxy technique and said lithography technique; and
etching back said second isolation layer.

11. The method for manufacturing a monolithic photo-chip with a solar device and a light-emitting device according to claim 10, wherein the material of said substrate is GaAs.

12. The method for manufacturing a monolithic photo-chip with a solar device and a light-emitting device according to claim 10, wherein the material of said first isolation layer is silicon oxide or silicon nitride.

13. The method for manufacturing a monolithic photo-chip with a solar device and a light-emitting device according to claim 10, wherein the material of said second isolation layer is silicon oxide or silicon nitride.

14. A method for manufacturing a monolithic photo-chip with a solar device and a light-emitting device, comprising the steps of:
providing a substrate;
covering a first isolation layer on said substrate and forming a first exposed region of said substrate;
forming a light-emitting device on said first exposed region of said substrate by using a epitaxy technique and a lithography technique;
etching back said first isolation layer;
covering a second isolation layer on said substrate and surfaces of said first device and forming a second exposed region of said substrate;
forming a solar device on said second exposed region of said substrate by using said epitaxy technique and said lithography technique; and
etching back said second isolation layer.

15. The method for manufacturing a monolithic photo-chip with a solar device and a light-emitting device according to claim 14, wherein the material of said substrate is GaAs.

16. The method for manufacturing a monolithic photo-chip with a solar device and a light-emitting device according to claim 14, wherein the material of said first isolation layer is silicon oxide or silicon nitride.

17. The method for manufacturing a monolithic photo-chip with a solar device and a light-emitting device according to claim 14, wherein the material of said second isolation layer is silicon oxide or silicon nitride.
